(19) United States
(12) Patent Application Publication
(10) Pub. No.: US 2026/0190238 A1
(43) Pub. Date: Jul. 2, 2026

(54) WIRING STRUCTURE OF ELECTRONIC COMPONENTS AND CONNECTION METHOD OF ELECTRONIC COMPONENTS

(71) Applicants: Shinichi MAEDA, Tokyo (JP); KEITA SMART FUTURE-CREATIONS INC., Tokyo (JP)

(72) Inventors: Shinichi MAEDA, Tokyo (JP); Keita MIYASATO, Tokyo (JP)

(21) Appl. No.: 18/868,488

(22) PCT Filed: Apr. 28, 2023
(86) PCT No.: PCT/JP2023/016798

§ 371 Date: Nov. 22, 2024

(30) Foreign Application Priority Data
May 31, 2022 (JP) 2022-089062

(51) Int. Cl. H05K 1/189; H05K 1/11; H05K 1/14; H05K 1/181; H05K 3/341; H05K 3/36

(52) U.S. Cl. CPC H05K 1/189; H05K 1/118; H05K 1/147; H05K 1/181; H05K 3/3421; H05K 3/363; H05K 2201/042

(57) ABSTRACT

A flexible wiring body (4) in which a conductive wiring portion (411) is formed at a flexible insulating base material (40) is interposed between a substrate (2) and an electronic component (3) installed on the substrate (2) such that the wiring portion (411) is electrically connected to the electronic component (3).

### TECHNICAL FIELD

The present invention relates to a wiring structure of electronic components used for an electrical device, an electronic device, a computer, a communication device, and the like and a connection method of the electronic components, and especially relates to a wiring structure of electronic components and a connection method of the electronic components appropriate for attempting a reduction of a transmission loss and improving the heat dissipation performance of a substrate in a high-speed and large-capacity transmission system.

### BACKGROUND ART

Conventionally, electronic components, such as a semiconductor element, a device, and an integrated circuit, used for an electrical device, an electronic device, a computer, a communication device, and the like are mounted on a printed wiring board (hereinafter referred to as a substrate). Conventionally, the use of a substrate made of a copper clad laminate using an epoxide-based resin or E-glass fiber has been applicable.

However, in a situation in which increased speed, increased capacity, and reduced latency of a transmission system are required as typified by the fifth-generation mobile communication system (5G), it becomes difficult to satisfy the required performance of the transmission loss to be necessary with the above-described conventional substrate. In addition, as a result of further miniaturization of semiconductor circuit wiring, after the 5G, it becomes more necessary to deal with especially the heat dissipation performance of a substrate. Especially, after the 5G, increased heat generation due to larger scale, increased speed, and higher integration of electronic components makes a measure against a breakdown caused by heat stress and a measure for heat dissipation important. The heat dissipation is difficult in an ordinary substrate because a ground (GND) layer having satisfactory heat conductivity cannot be sufficiently arranged at an outermost layer. Especially, increased heat generation due to larger scale, increased speed, and higher integration of electronic components requires a measure against a breakdown caused by heat stress and a measure for heat dissipation as urgent issues.

In view of this, recently, to meet the required properties of the transmission loss and the heat dissipation performance required in such a high-speed transmission system, the following improvements have been attempted.

To reduce the transmission loss, the circuit design of a semiconductor and the wiring circuit design of a substrate have been improved. Also for the material of a substrate, various improvements have been made. To improve the heat dissipation performance, in addition to the improvement of the substrate material described above, the installation of a blast fan, the mounting of a heat sink to a semiconductor package, further, the installation of an air cooling or water cooling mechanism, and the like have been attempted.

However, to attempt further improvement of a low dielectric property and a high heat dissipation performance, it is necessary to improve the substrate material and perform a reliability verification test thereof, and it takes a long time to achieve it. Especially, in an attempt to further improve a low dielectric property of the substrate material, the degree of difficulty in product design thereof significantly increases, and substrate material costs, substrate development costs, and the like also increase.

Further, as a result of a significant increase of the transmission loss in a high frequency bandwidth, restrictions on the circuit design of a substrate increases. E-glass cloth generally used as a substrate material is appropriate from the aspect of avoiding thermal expansion of a substrate and ensuring mechanical strength, but meanwhile, the E-glass cloth may cause a reduction in electrical characteristics typified by the dielectric constant and the dielectric loss tangent and the surface smoothness required of the substrate.

In a multi-layer wiring board, because of an increase of wiring density, X-Y wiring in which wiring layers are switched with vias is often used, but there is a disadvantage that the vias adversely affect the transmission loss, and longer wiring increases the transmission loss.

To avoid the electric property reduction and the wiring density reduction due to the vias, in a multi-layer substrate, an interstitial via hole (IVH) for connecting only necessary layers without making a hole pass through, a back drill, and the like are used, but the substrate costs increase, and the substrate circuit design is restricted.

Meanwhile, a method in which instead of improving the material and the structure themselves of a substrate, electronic components are mutually electrically connected not via the substrate but by direct connection via a connector is considered. However, in such a method, the connector needs to be attached to the electronic component or in the proximity of the electronic component. It is often difficult to ensure an area for attaching the connector in the electronic component more reduced in size, and further, the transmission loss is generated in the connector in some cases.

Furthermore, in the ordinary substrate, since the electronic components are directly connected, when a part of the electronic components are broken, there is a problem that the convenience in the repair is reduced.

To solve the above-described conventional problems, the following techniques of Patent Documents 1 and 2 are proposed. In the technique disclosed in Patent Document 1, integrated circuit packages installed on a substrate are directly coupled via a direct connect cable. In the technique disclosed in Patent Document 2, circuit boards on which semiconductor elements are provided are thermally connected to one another via a member.
Patent Document 1: JP-A-2010-192918
Patent Document 2: JP-A-2016-213361

### DISCLOSURE OF THE INVENTION

### Problems to be Solved by the Invention

However, the techniques disclosed in Patent Documents 1 and 2 described above do not intend the improvement of the transmission loss or the heat dissipation performance. Therefore, it is not especially mentioned to electrically connect electronic components installed on a substrate via a wiring body other than the substrate.

Therefore, the present invention has been made in consideration of the above-described problem, and it is an object of the present invention to provide a wiring structure of electronic components and a connection method of the electronic components appropriate for attempting a reduction of a transmission loss and improving the heat dissipation performance of a substrate in a high-speed and large-capacity transmission system.

### Solutions to the Problems

To solve the above-described problem, the present inventors invented a wiring structure of electronic components and a connection method of the electronic components in which a flexible wiring body including a conductive wiring portion formed on a flexible insulating base material is interposed between a substrate and an electronic component installed on the substrate so as to electrically connect the wiring portion to the electronic component.

A wiring structure of electronic components according to a first invention includes a substrate and a flexible wiring body interposed between the substrate and an electronic component installed on the substrate. The flexible wiring body is provided with a conductive wiring portion and has flexibility. The wiring portion of the flexible wiring body is electrically connected to the electronic component and/or the substrate. The flexible wiring body, the substrate, and the electronic component are directly electrically connected in an area in which the flexible wiring body is interposed. The wiring portion of the flexible wiring body electrically connects two or more mutually spaced electronic components installed on the one substrate to one another, and an area of the flexible wiring body between the electronic components is separated from the substrate.

In the wiring structure of electronic components according to a second invention, which is in the first invention, the wiring portion provided at any one end side or both end sides of the flexible wiring body electrically connects the two or more electronic components installed on the one substrate to one another, or electrically connects the electronic components set on the respective two or more substrates to one another.

In the wiring structure of electronic components according to a third invention, which is in the first invention or the second invention, a plurality of the flexible wiring bodies are stacked, and the wiring portions of the respective flexible wiring bodies are electrically connected to the one electronic component.

The wiring structure of electronic components according to a fourth invention, which is in the first invention or the second invention, further includes another substrate provided below the substrate. Another flexible wiring body is further interposed between the substrate and the other substrate, and the other flexible wiring body includes a wiring portion electrically connected to the substrate.

In the wiring structure of electronic components according to a fifth invention, which is in the first invention or the second invention, the wiring portion of the flexible wiring body is provided at each layer of two or more layers of conductor portions.

A wiring structure of electronic components according to a sixth invention includes a housing and a flexible wiring body interposed between the housing and an electronic component installed on an inner wall surface that functions as a substrate of the housing. The flexible wiring body is provided with a conductive wiring portion and has flexibility. The wiring portion of the flexible wiring body is electrically connected to the electronic component and/or a wiring portion formed on the inner wall surface of the housing. The flexible wiring body, the inner wall surface of the housing, and the electronic component are directly electrically connected in an area in which the flexible wiring body is interposed. The wiring portion of the flexible wiring body electrically connects two or more mutually spaced electronic components separately installed on the inner wall surface and another substrate to one another, and the electronic components at the flexible wiring body are spaced.

A connection method of electronic components according to a seventh invention includes: interposing a flexible wiring body that is provided with a conductive wiring portion and has flexibility between a substrate and an electronic component installed on the substrate such that the wiring portion is electrically connected to the electronic component and/or the substrate; directly electrically connecting the flexible wiring body, the substrate, and the electronic component in an area in which the flexible wiring body is interposed; and electrically connecting two or more mutually spaced electronic components installed on the one substrate to one another by the wiring portion of the flexible wiring body, and separating an area of the flexible wiring body between the electronic components from the substrate.

In the connection method of electronic components according to an eighth invention, which is in the seventh invention, the wiring portion provided at any one end side or both end sides of the flexible wiring body electrically connects the two or more electronic components installed on the one substrate to one another, or electrically connects the electronic components set on the respective two or more substrates to one another.

In the connection method of electronic components according to a ninth invention, which is in the seventh invention or the eighth invention, when a plurality of the flexible wiring bodies are stacked, the wiring portions of the respective flexible wiring bodies are electrically connected to the one electronic component.

### Effects of the Invention

According to the present invention with the above-described configuration, especially after the 5G, in a situation in which increased speed, increased capacity, and reduced latency of a transmission system are required, the transmission loss performance and the like can be improved. Especially, in the flexible wiring body, the wiring between the electronic components can be linearly made, and this is effective in a reduction of a transmission loss due to the wiring length. In addition, the optimization of the material of the flexible wiring body can enhance the possibility of the application to the required transmission system. The optimization of the materials of the conductor portion and a conductive portion can enhance the possibility of the application to the required transmission system.

According to the present invention with the above-described configuration, especially after the 5G, when heat is generated due to larger scale, increased speed, and higher integration of an electronic component, the heat dissipation performance can be improved by separating the flexible wiring body from the substrate. Especially, since the flexible wiring body includes the conductor portion, the heat from the electronic component can be effectively released. In addition, by interposing the flexible wiring body between the electronic component and the substrate, the distance between the electronic component and the substrate can be increased, and the heat dissipation property and the cooling property can be further improved. Especially, by extending the wiring portion formed of the conductor portion over a wide area, the heat released from the electronic component can be efficiently conducted and diffused to the flexible wiring body by the heat conductivity of the conductor portion. While the heat transmitted to the flexible wiring body is released from the surface, the space between the substrate and the flexible wiring body allows enhancing the efficiency of air cooling or liquid cooling.

### BRIEF DESCRIPTION OF THE DRAWINGS

FIG. 1 is a cross-sectional schematic diagram of a wiring structure of electronic components to which the present invention is applied.

FIG. 2 is a plan view illustrating connection points provided at both ends of a wiring portion.

FIG. 3 is a plan view of another example illustrating the connection points provided at the wiring portion.

FIG. 4 is a cross-sectional view of a first cross-sectional surface in FIG. 2.

FIG. 5 is a drawing illustrating conductive portions constituting the respective connection points in detail.

FIG. 6 is a drawing for describing more detailed configurations of the conductive portions illustrated in FIG. 5.

FIG. 7 is a drawing illustrating connection examples between an electronic component with rod-shaped terminals and a flexible wiring body.

FIG. 8 is a drawing illustrating an example in which when the flexible wiring body is provided between electronic components, the flexible wiring body is elastically deformed so as to extend over other electronic components.

FIG. 9 is a drawing illustrating examples of the planar arrangement of the flexible wiring body.

FIG. 10 is a drawing illustrating an example in which a plurality of electronic components are connected to one electronic component by the flexible wiring bodies.

FIG. 11 is a drawing illustrating an example in which the two or more flexible wiring bodies are stacked.

FIG. 12A is a drawing illustrating an example in which the two flexible wiring bodies are stacked, and FIG. 12B is a drawing illustrating an example of being configured of only the one flexible wiring body.

FIG. 13 is a drawing illustrating a configuration of holding an area of the flexible wiring body interposed between the substrate and the electronic component by gap holding bodies over a predetermined gap.

FIG. 14 is a drawing for describing a method for installing the gap holding bodies illustrated in FIG. 13.

FIG. 15 is a drawing illustrating an example in which the wiring structure is provided at a housing instead of the substrate.

FIG. 16 is a drawing for describing a configuration in which not all the terminals are electrically connected to the flexible wiring body with respect to the electronic component.

FIG. 17 is a drawing illustrating an example of further including another substrate provided below the substrate.

FIG. 18 is a drawing illustrating an example in which a plurality of layers of conductor portions are provided inside the flexible wiring body.

FIG. 19 is a drawing illustrating an example in which the above-described wiring portion is provided at one end side of the flexible wiring body and the other end side is configured of a connector.

### DESCRIPTION OF PREFERRED EMBODIMENTS

The following describes a wiring structure of electronic components to which the present invention is applied in detail with reference to the drawings.

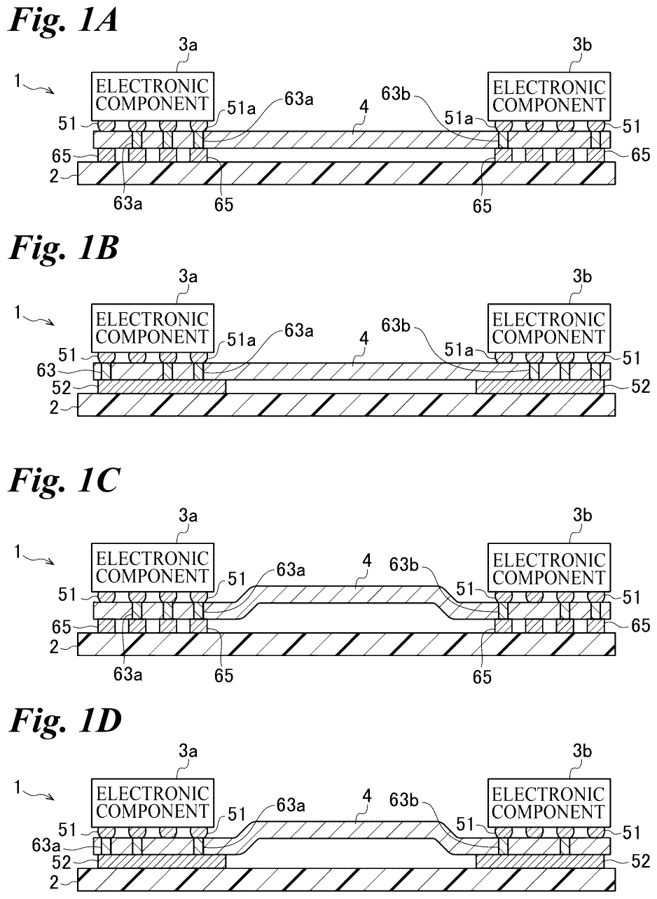

FIGS. 1A and 1C are cross-sectional schematic diagrams of a wiring structure 1 of electronic components to which the present invention is applied. The wiring structure 1 includes a substrate 2, two or more electronic components 3a, 3b installed on the substrate 2, and a flexible wiring body 4 interposed between the substrate 2 and an electronic component 3. The electronic components 3a, 3b are connected to the substrate 2 via conductive portions 51. The flexible wiring body 4 is connected to the substrate 2 via conductive portions 65. In the wiring structure 1 of electronic components to which the present invention is applied, the electronic component 3a and the electronic component 3b are electrically connected to one another via one or both of the substrate 2 and the flexible wiring body 4.

The substrate 2 is what is called a printed wiring board, and conductors are wired on or inside a board configured of an insulator. The substrate 2 may be configured of a board to which a plurality of printed wiring boards are attached or connected. A printed wiring board of any of a single-sided board (a wiring portion of one layer), a double-sided board (a wiring portion of two layers), and a multi-layer board (a wiring portion of three or more layers) may be applied to the substrate 2.

The electronic component 3 includes any component mountable to the substrate 2, for example, a semiconductor element, a device, an integrated circuit, and a module. Particularly, the electronic component 3 is especially effective in an element, a module, and the like having many input/output signals of high speed, low speed, a power source, and the like. The electronic component 3 includes one directly electrically connected to the substrate 2 and one electrically connected to the flexible wiring body 4.

The conductive portion 51 and the conductive portion 65 are configured of what is called solder, but not limited thereto, and any conductive portion may be used insofar as the conductive portion is configured of a conductive material.

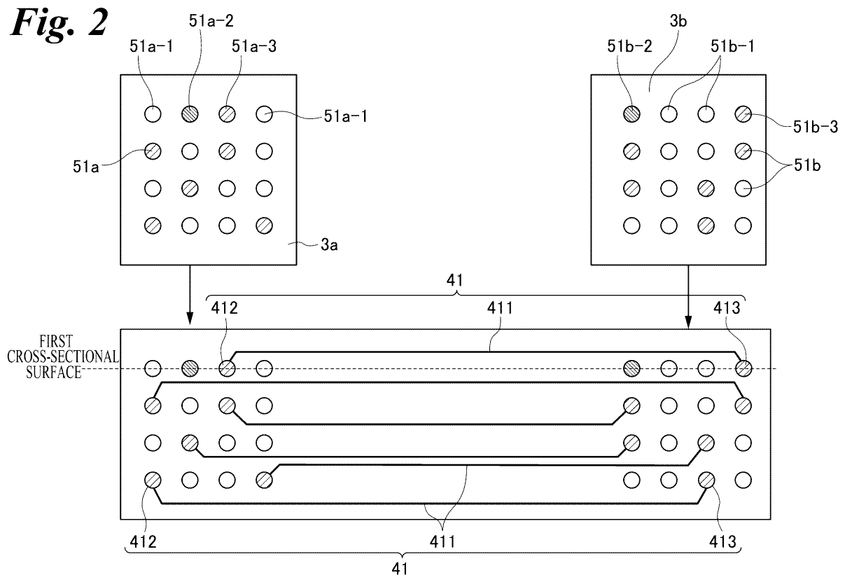

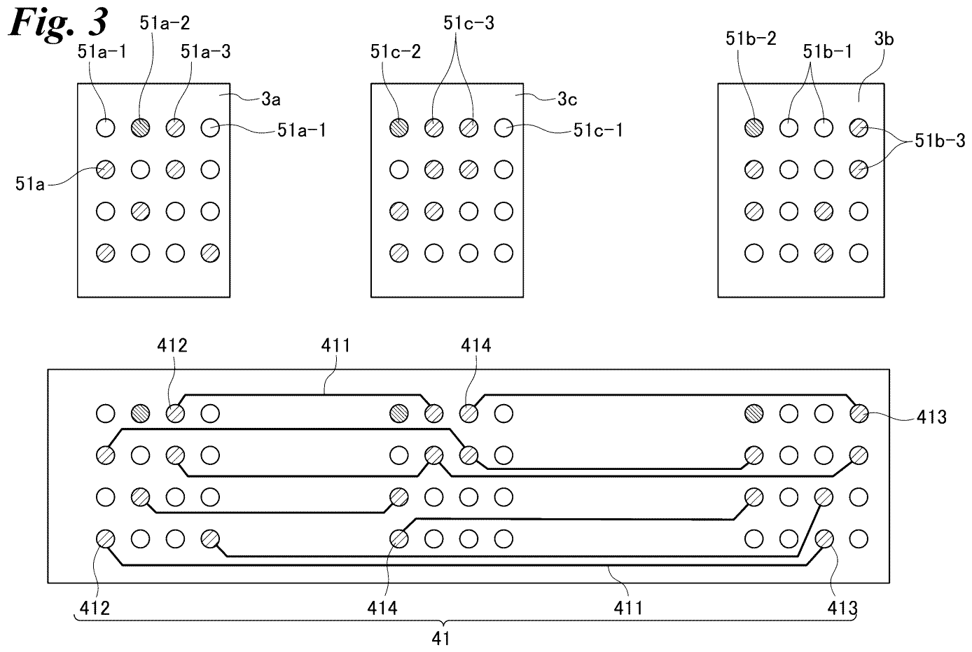

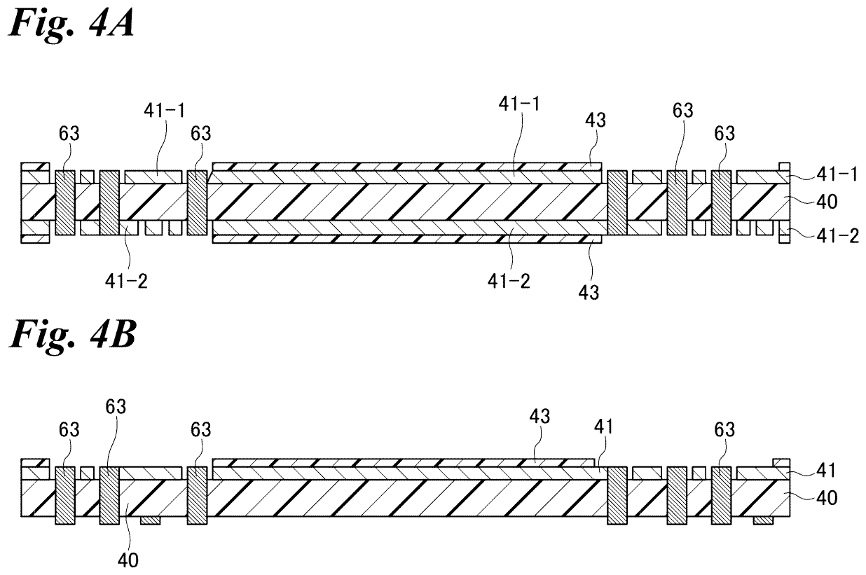

FIGS. 2 and 3 are plan views illustrating a correspondence relation between the bottom surface of the electronic component 3a and the upper surface of the flexible wiring body 4 that are mutually joined. FIG. 4A is a cross-sectional view of a first cross-sectional surface in FIG. 2. The flexible wiring body 4 includes, as illustrated in FIG. 4, a conductor portion 41-1 formed on the upper surface of a base material 40 and a conductor portion 41-2 formed on the lower surface of the base material 40, and further, the upper surface of the conductor portion 41-1 and the lower surface of the conductor portion 41-2 are coated with a coating layer 43. The flexible wiring body 4 is provided with conductive portions 63 for electrical connection with the electronic component 3 at respective positions.

The base material 40 only needs to be configured of a flexible insulating material. The flexible insulating material may be configured of, for example, an organic substrate, and may be polyimide, modified polyimide, polyethylene terephthalate, liquid crystal polymer, polyethylene naphthalate, fluorine-based polymer, phenol, epoxy, polyphenylene oxide (PPO), polyphenylene ether (PPE), polyetherimide, polyesterimide, or the like. An organic material used for the organic substrate may be thermosetting or thermoplastic.

The base material 40 may be configured of an inorganic substrate, and may be an insulating sheet made of a glass sheet or another inorganic material, ceramics, or the like.

The base material 40 may be an organic/inorganic composite substrate insofar as the flexibility is provided. An organic moiety may be polyimide, modified polyimide, polyethylene terephthalate, liquid crystal polymer, polyethylene naphthalate, fluorine-based polymer, phenol, epoxy, PPO, PPE, polyetherimide, polyesterimide, or the like, and an inorganic moiety may be a glass material or another inorganic material.

The glass material or the other inorganic material constituting the base material 40 may have any shape including sheet, fiber, short fiber, filler (grain, powder, and the like), and the like. Further, they may be processed in any shape including paper, mat, cloth, and the like.

Insofar as the flexibility is provided, an organic material or an organic/inorganic composite material may be used for the base material 40 instead of the inorganic material.

The base material 40 configured of the material as described above is configured to be freely elastically deformed.

The conductor portions 41-1, 41-2 are layers constituting actual wiring. Actually, means of etching or the like is performed on a conductor portion 41, thereby constituting a desired wiring shape. FIGS. 2 and 3 illustrate a wiring portion 411 formed by performing the means of etching or the like on the conductor portion 41, and connection points 412, 413, 414 provided at both ends of the wiring portion 411.

The wiring portion 411 is linearly formed such that the connection points 412, 413 can be mutually electrically connected. The connection points 412, 413 are electrically connected to the electronic component 3. In FIG. 3, the wiring portion 411 is linearly formed such that the connection points 412, 413, 414 can be mutually electrically connected. The connection points 412, 413, 414 are electrically connected to the electronic component 3.

The coating layer 43 is formed to coat the upper and the lower surfaces of the flexible wiring body 4. However, the coating layer is not provided in some cases.

The coating layer 43 is configured of, for example, a film type using any material including a polyimide base and a PET base, or a print type using any material including an epoxy resin base and a urethane resin base. The coating layer 43 may be configured of a photosensitive type using a photosensitive film or a photosensitive ink, or the like. The coating layer 43 is not particularly limited insofar as the conductor portion 41 can be coated. By coating the surface of the conductor portion 41 with the coating layer 43, the conductor portion 41 can be configured not to be directly exposed. As a result, rust on, a scratch on, and damage to the conductor portion 41 can be avoided. The wiring portion 411 of the flexible wiring body 4 can mutually electrically connect the respective two or more electronic components 3 installed on the substrate 2. In FIG. 2, the connection point 412 of the wiring portion 411 is electrically connected via a conductive portion 51a of one electronic component 3a. The connection point 413 of the wiring portion 411 is connected via the conductive portion 51a of another electronic component 3b. As a result, the conductive portion 51a of the one electronic component 3a and the conductive portion 51a of the other electronic component 3b are mutually electrically connected via the wiring portion 411.

In the case of FIG. 3, similarly, the connection point 412 of the wiring portion 411 is electrically connected via the conductive portion 51a of one electronic component 3a. The connection point 413 of the wiring portion 411 is connected via the conductive portion 51a of another electronic component 3b. Further, the connection point 414 of the wiring portion 411 is connected via a conductive portion 51c of another electronic component 3c. As a result, the conductive portion 51a of the one electronic component 3a, the conductive portion 51a of the other electronic component 3b, and the conductive portion 51c of the still other electronic component 3c are mutually electrically connected via the wiring portion 411.

The wiring portion 411 may be formed by attaching the conductor portion 41 and then performing circuit formation, or may be formed by depositing a conductor by plating or the like. Further, while there are a technique of printed electronics and the like and a method of using them together, any method may be applied insofar as at least the wiring portion 411 can be formed.

At this time, electrical connection between a part of terminals 31a of the one electronic component 3a and a part of terminals 31b of the other electronic component 3b can be made by using the flexible wiring body 4 without the substrate 2.

While it is assumed that the flexible wiring body 4 is configured to have a two-layer structure of the conductor portion 41-1 formed on the upper surface of the base material 40 and the conductor portion 41-2 formed on the lower surface of the base material 40 like the configuration illustrated in FIG. 4A, it is not limited thereto, and the flexible wiring body 4 may be configured to have a one-layer structure of only the conductor portion 41 formed on the upper surface of the base material 40 as illustrated in FIG. 4B. In this case, the formation of the coating layer 43 on the lower surface of the base material 40 can be omitted. In both the one-layer structure and the two-layer structure, the formation of the coating layer 43 is not necessarily required, and the formation of the coating layer 43 on the upper surface and the lower surface of the flexible wiring body 4 may be omitted. It is needless to say that the conductor portion 41 may be configured of three or more layers.

In the flexible wiring body 4, the base material 40 is configured to be freely elastically deformed, and the conductor portion 41 and the coating layer 43 stacked thereon are also configured to be freely elastically deformed following the base material 40. Therefore, as illustrated in FIG. 1, the flexible wiring body 4 may be freely elastically deformed and fixed in a folded state even without elastically deforming the flexible wiring body 4. That is, in a case where two or more electronic components 3 installed on one substrate 2 are mutually electrically connected via the flexible wiring body 4, an area of the flexible wiring body 4 between the electronic components 3 is separated from the substrate 2. Thus, especially after the 5G, while heat is generated due to larger scale, increased speed, and higher integration of the electronic component 3 in some cases, separating the flexible wiring body 4 from the substrate 2 allows improvement of the heat dissipation performance. In particular, since the flexible wiring body 4 is provided with the conductor portion 41, the heat from the electronic component 3 can be effectively released. In addition, by interposing the flexible wiring body 4 between the electronic component 3 and the substrate 2, a distance between the electronic component 3 and the substrate 2 can be increased, thus allowing further improvement of the heat dissipation property and the cooling property. Especially, by extending the wiring portion 411 formed of the conductor portion 41 over a wide area, the heat released from the electronic component 3 can be efficiently conducted and diffused to the flexible wiring body 4 by the high heat conductivity of copper. While the heat transmitted to the flexible wiring body 4 is released from the surface, the space between the substrate 2 and the flexible wiring body 4 allows enhancing the efficiency of air cooling or liquid cooling.

In the flexible wiring body 4, as illustrated in FIGS. 2 and 3, the conductive portions 51 provided at the electronic component 3 are connected to the respective connection points 412, 413, 414 of the flexible wiring body 4.

Here, conductive portions 51a-1, 51b-1, 51c-1 are terminals, bumps, or the like for electrical connection to only a conductor portion 21 of the substrate 2 without connection to the conductor portion 41 of the flexible wiring body 4. Conductive portions 51a-2, 51b-2, 51c-2 are terminals, bumps, or the like for electrical connection to both the conductor portion 41 of the flexible wiring body 4 and the conductor portion 21 of the substrate 2. Conductive portions 51a-3, 51b-3, 51c-3 are terminals, bumps, or the like for electrical connection to only the conductor portion 41 of the flexible wiring body 4. These respective conductive portions 51a, 51b are continuous with the flexible wiring body 4 via the above-described conductive portions 51a.

In the case of the first cross-sectional surface as an example, as illustrated in FIG. 4, portions corresponding to the respective connection points 412, 413 of the flexible wiring body 4 are configured of the conductive portions 63 provided in an up-down direction.

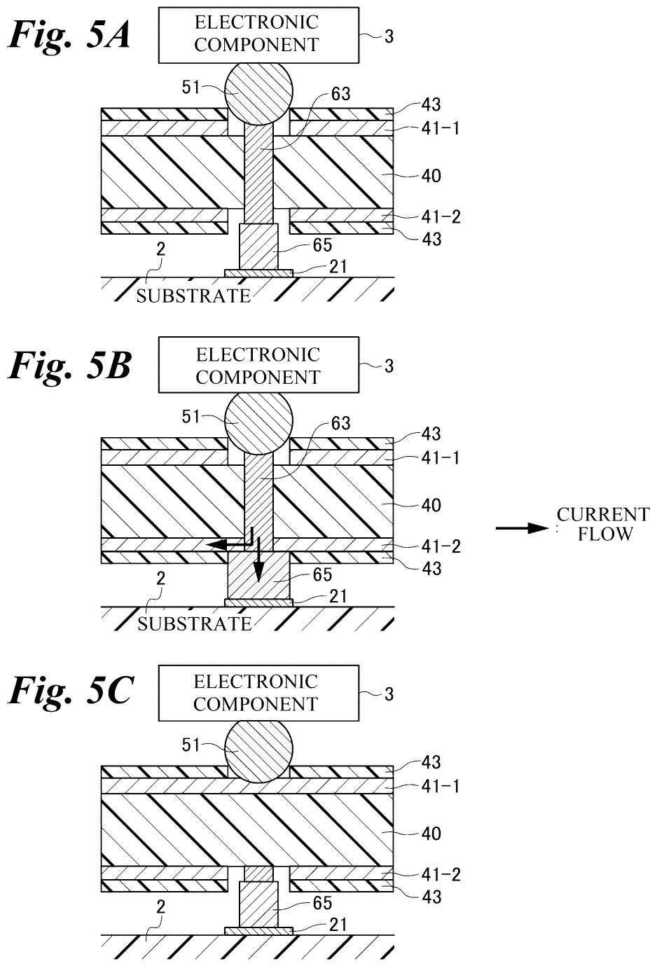

FIG. 5 illustrates the conductive portion in detail. FIG. 5A illustrates an exemplary configuration in which the conductive portions 51a-1, 51b-1, and the like are electrically connected to only the conductor portion 21 of the substrate 2 without being connected to the conductor portion 41 of the flexible wiring body 4. The conductive portion 63 may be the above-described connection points 412, 413. The conductive portion 63 is configured by embedding a conductor in a hole formed at the base material 40. At the portion at which the conductive portion 63 is formed, the coating layer 43 is removed without being formed. Consequently, the conductive portion 63 is configured to be directly exposed to the outside.

The conductive portion 51 interposed between the electronic component 3 and the conductive portion 63 is melted, thereby allowing electrically connecting them. In the configuration illustrated in the example of FIG. 5A, the conductive portion 63 can be separated from the conductor portions 41-1, 41-2 not to make a current flowing through the conductive portion 63 flow to the conductor portions 41-1, 41-2. The conductive portion 63 is connected to the conductive portion 65 formed between the substrate 2 and the flexible wiring body 4. Therefore, the current flowing through the conductive portion 63 can be made to flow to the conductor portion 21 of the substrate 2 via the conductive portion 65.

FIG. 5B illustrates an exemplary configuration in which the conductive portions 51a-2, 51b-2, and the like are electrically connected to both the conductor portion 41 of the flexible wiring body 4 and the conductor portion 21 of the substrate 2. In the example illustrated in FIG. 5B, the conductive portion 63 is separated from the conductor portion 41-1. Meanwhile, the conductive portion 63 is connected to the conductor portion 41-2. This allows having a configuration in which the current flowing through the conductive portion 63 is made to flow to the conductor portion 41-2 without being made to flow to the conductor portion 41-1. The conductive portion 63 is connected to the conductive portion 65 formed between the substrate 2 and the flexible wiring body 4. Therefore, the current flowing through the conductive portion 63 can be made to flow to the conductor portion 21 of the substrate 2 via the conductive portion 65.

In the configuration illustrated in FIG. 5B, by having a configuration in which the conductive portion 63 is further connected to the conductor portion 41-1, in addition to both the conductor portions 41-1, 41-2, the conductor portion 21 of the substrate 2 can be electrically connected to the electronic component 3. Further, by connecting the conductive portion 63 to the conductor portion 41-1 and separating the conductive portion 63 from the conductor portion 41-2, the conductor portion 41-1 and the conductor portion 21 of the substrate 2 can be electrically connected to the electronic component 3 while the conductor portion 41-2 can be made not electrically connected to the electronic component 3.

FIG. 5C illustrates an exemplary configuration in which the conductive portions 51a-3, 51b-3, and the like are electrically connected to only the conductor portion 41 of the flexible wiring body 4. In the example illustrated in FIG. 5C, the electronic component 3 is connected to an exposed area of the conductor portion 41-1 via the conductive portion 51, thereby allowing electrical connection to one another. Since the conductor portion 41-1 is insulated from the conductor portion 41-2 and the conductive portion 65 via the base material 40, only the conductor portion 41-1 can be electrically connected to the electronic component 3, and the conductor portion 41-2 and the conductive portion 65 can be made not electrically connected to the electronic component 3.

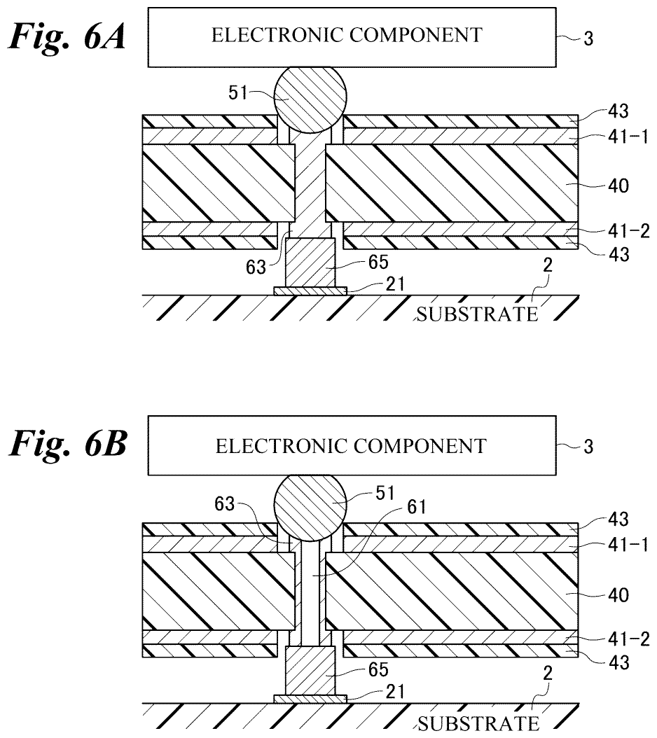

FIG. 6A illustrates an example in which the conductive portion 63 is configured of a material same as that of the conductor portion 41 in the configuration in which the conductive portion 63 is separated from the conductor portions 41-1, 41-2 as illustrated in FIG. 5A. The conductive portion 63 is configured not to be electrically connected by being separated from the conductor portions 41-1, 41-2.

FIG. 6B illustrates an example in which the conductive portion 63 is configured of a conductive film formed on side end surfaces of the base material 40. While the film-shaped conductive portion 63 is configured to coat the side end surfaces and the upper and lower surfaces of the base material 40, the conductive portion 63 is configured not to be electrically connected by being separated from the conductor portions 41-1, 41-2. With such a configuration of the film-shaped conductive portion 63, the conductive portion 63 is provided with a hole 61 penetrating in the up-down direction at the center. When the electronic component 3 is configured of a pin-shaped terminal, it can be inserted via the hole 61 formed at the conductive portion 63.

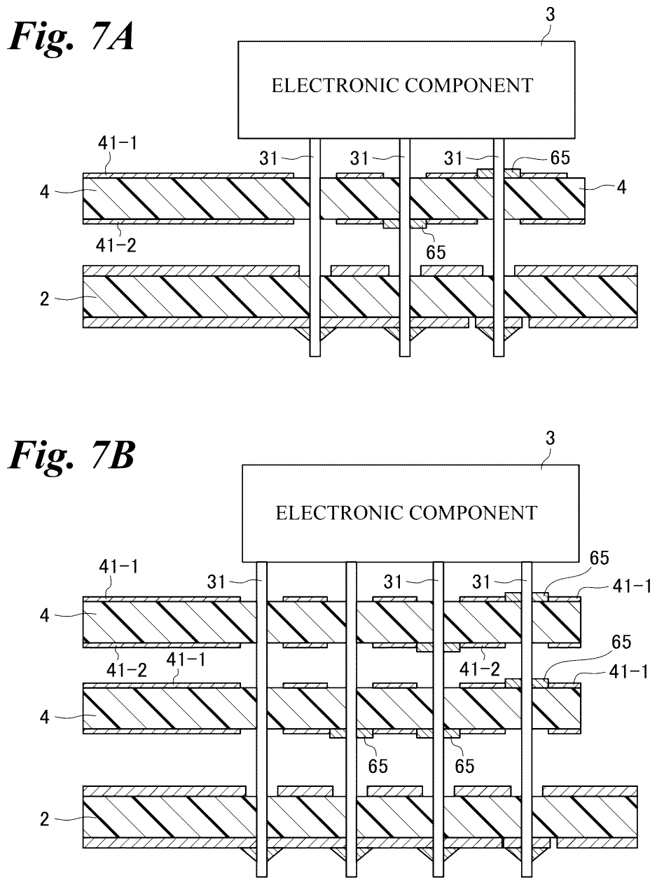

FIG. 7 illustrates an exemplary connection between the electronic component 3 provided with rod-shaped terminals 31 and the flexible wiring body 4. In the example of FIG. 7, the configuration of the coating layer 43 provided at the flexible wiring body 4 is omitted.

The rod-shaped terminals 31 are directly connectable to the substrate 2. Further, to achieve electrical connection between the terminals 31 and the conductor portions 41-1, 41-2 in the flexible wiring body 4, the conductive portion 65 electrically connected to any one or both of the conductor portions 41-1, 41-2 for which the electrical connection is desired is provided. The conductive portion 65 may be configured not to be connected to the substrate 2. Such electrical connection between the conductive portion 65 and the terminal 31 allows electrical connection with the conductor portions 41-1, 41-2. FIG. 7A illustrates an example of a configuration with one flexible wiring body 4, FIG. 7B illustrates an example of a configuration with two flexible wiring bodies, and both are embodied with a similar configuration.

In the wiring structure 1 of the electronic components to which the present invention is applied, for the connection between the substrate 2 and the flexible wiring body 4, in addition to the connection using the conductive portion 51, it is only necessary that the conductive portion 51 can make an electrical connection from the electronic component 3 to the substrate 2 or the flexible wiring body 4 as illustrated in FIGS. 1B and 1D. As one example, press-bonding or the like of an anisotropic conductive film (ACF) 52 may be performed. In this case, the ACF 52 is interposed between the substrate 2 and the flexible wiring body 4 in advance, and then press-bonding is performed, thereby allowing connection to one another.

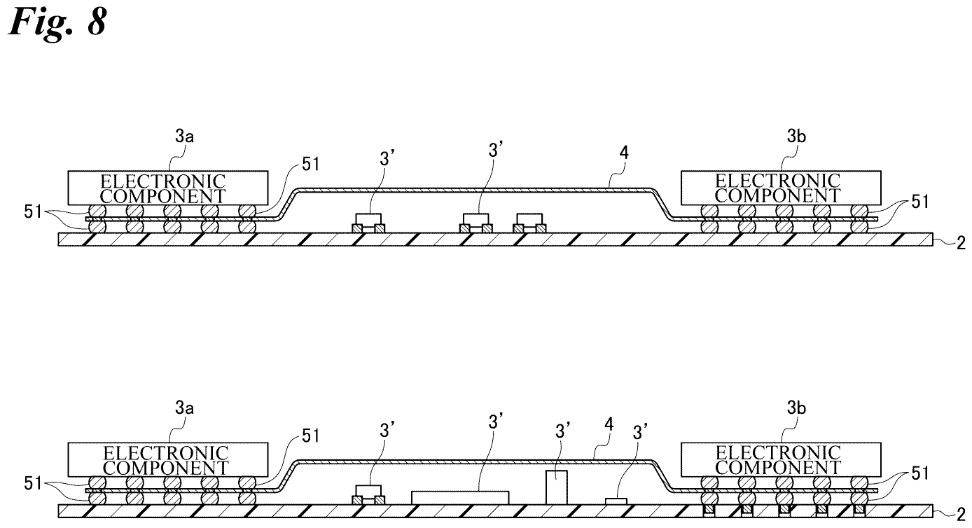

In a case where other electronic components 3′ are already attached on the substrate 2 as illustrated in FIG. 8, when the flexible wiring body 4 is provided from the electronic component 3a to the electronic component 3b, the flexible wiring body 4 may be elastically deformed so as to extend over the other electronic components 3′. This allows providing the flexible wiring body 4 while maintaining the arrangement of the other electronic components 3′ already attached on the substrate 2 as it is. Thus, by elastically deforming the elastically deformable flexible wiring body 4 and separating an area between the electronic component 3a and the electronic component 3b from the substrate 2, the arrangement of the electronic components 3′ can be maintained as it is.

Even when a heat sink is attached to the electronic component 3, since the heat dissipation performance can be improved as described above, the similar level of heat dissipation performance can be ensured even with a lower height of the heat sink to be attached. Therefore, since the downsizing or removal of the heat sink can be attempted, the cost can be reduced. Further, with an attempt of a reduction in volume or the removal of the heat sink, the convenience can be improved even in the installation at a small-sized device.

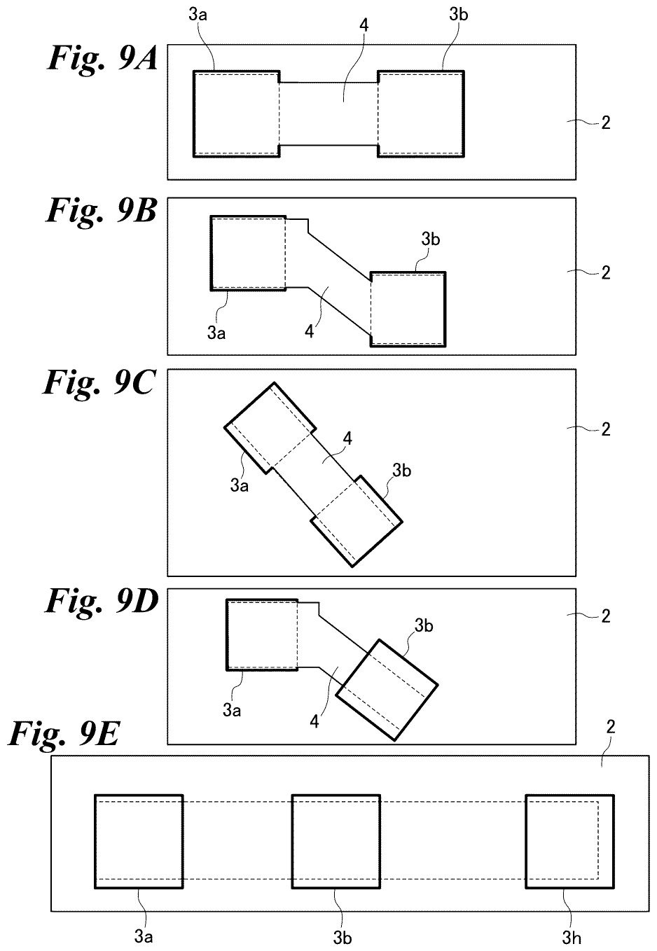

The flexible wiring body 4 may freely connect the electronic component 3a to the electronic component 3b to be electrically connected corresponding to a planar arrangement thereof like plan views of the wiring structure 1 illustrated in FIGS. 9A, 9B, 9C, 9D, and 9E. Especially, the electronic component 3a and the electronic component 3b may be planarly arranged linearly in a lateral direction to one another as illustrated in FIG. 9A, and the electronic component 3a and the electronic component 3b may be planarly arranged toward an oblique direction to one another as illustrated in FIGS. 9B, 9C, and 9D. The electronic component 3a, the electronic component 3b, and an electronic component 3h may be planarly arranged as illustrated in FIG. 9E. At this time, the number of the electronic components 3 may be any number insofar as two or more electronic components 3 are continuously arranged. Elastically deforming the flexible wiring body 4 in the oblique direction or elastically twisting the flexible wiring body 4 itself also allows the connection thereof.

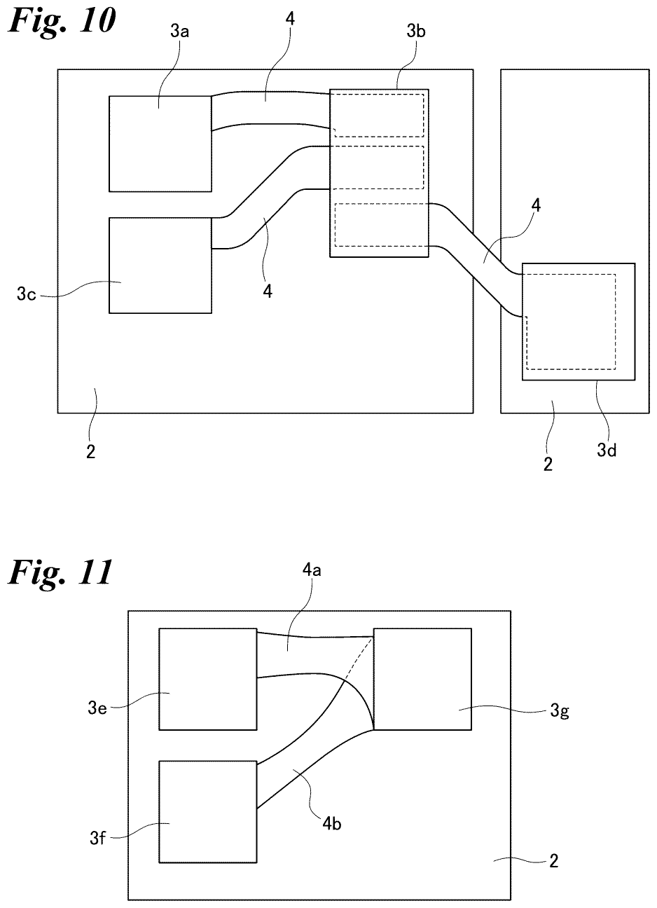

As illustrated in FIG. 10, a plurality of electronic components 3a, 3c, 3d may be connected to one electronic component 3b by the flexible wiring bodies 4. At this time, the electronic component 3c installed on the same substrate 2 as the electronic component 3b may be connected by the flexible wiring body 4, and the electronic component 3d installed on the different substrate 2 from the electronic component 3b may be connected by the flexible wiring body 4.

Thus, the use of the flexible wiring body 4 allows electrical connection between the electronic components 3 regardless of whether the electronic components 3 are installed on one substrate 2 or the electronic components 3 are installed on respective two or more substrates 2.

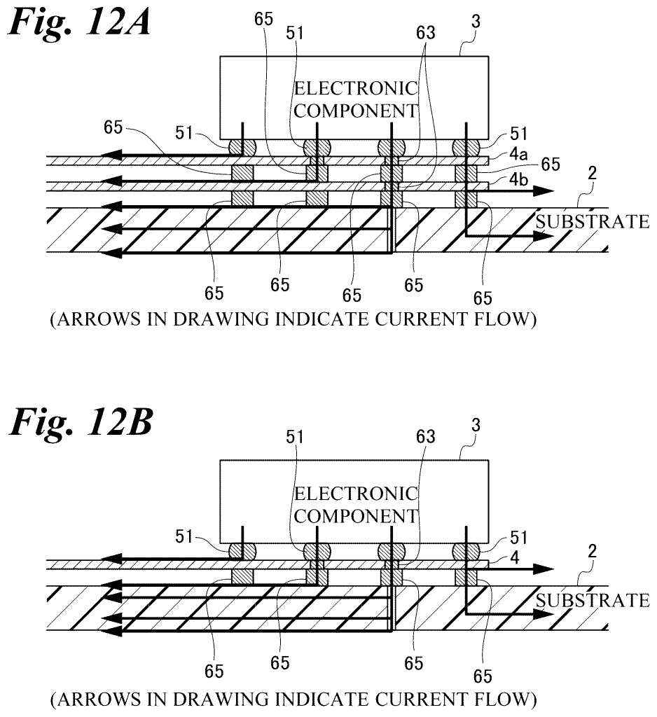

As illustrated in FIG. 11, when two or more electronic components 3e, 3f are connected to one electronic component 3g, a plurality of flexible wiring bodies 4 may be stacked at the electronic component 3g side. In this case, as illustrated in FIG. 12A, a flexible wiring body 4a connected to the electronic component 3e and a flexible wiring body 4b connected to the electronic component 3f are mutually stacked, and electrically connected to the conductive portion 63 of the electronic component 3g via the wiring portion 411. The flexible wiring body 4a and the flexible wiring body 4b are mutually connected via the conductive portions 65. The flexible wiring body 4b and the substrate 2 are also mutually connected via the conductive portions 65.

Consequently, as illustrated in FIG. 12A, in addition to the electrical connections between the electronic component 3 and the flexible wiring body 4a and between the electronic component 3 and the flexible wiring body 4b, the electrical connection between the electronic component 3 and the substrate 2 can be made. In addition to the electronic component 3, the flexible wiring body 4a and the flexible wiring body 4b can be electrically connected to the substrate 2.

The parallel/series connection of current can be achieved by adjusting the position at which the conductive portion 63 is provided in the flexible wiring body 4a and the flexible wiring body 4b. That is, in a case of electrical connection by making electricity flow in the up-down direction through the respective flexible wiring bodies 4a, 4b, through-holes are provided, and plating is performed there or a conductive material is embedded therein to form the conductive portions 63, thereby forming the connection points 412, 413. Meanwhile, in a case where electricity is not made to flow in the up-down direction through the respective flexible wiring bodies 4a, 4b and electrical connection is not made, the flexible wiring bodies 4a, 4b remain as they are without providing through-holes. Thus, by appropriately selecting the positions at which the connection points 412, 413 are formed, the above-described desired parallel/series connection can be achieved.

When the desired parallel/series connection as described above is achieved, as illustrated in FIG. 12B, the desired parallel/series connection can be achieved similarly in a case of a configuration with only one flexible wiring body 4.

This allows connecting the flexible wiring body 4a and the flexible wiring body 4b to the conductive portion 63 of one electronic component 3 in common. That is, the conductive portion 63 of the one electronic component 3g can be electrically connected to the mutually different electronic components 3e, 3f in common via the flexible wiring bodies 4a, 4b, respectively.

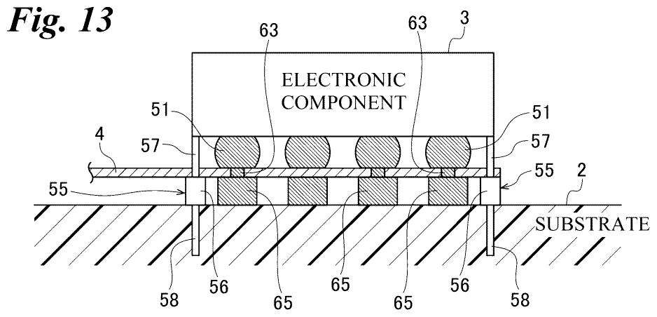

FIG. 13 illustrates an example for embodying the present invention. The area of the flexible wiring body 4 interposed between the substrate 2 and the electronic component 3 may be held by gap holding bodies 55 over a predetermined gap. The gap holding body 55 includes a base portion 56, a pin 57 projecting upward from the base portion 56, and a pin 58 projecting downward from the base portion 56. The gap holding body 55 may be configured of any material including resin, metal, ceramics, and the like.

The electronic component 3 is placed at upper ends of the pins 57. The pins 58 are inserted into the substrate 2 and secured. The base portions 56 are placed on the substrate 2, and the flexible wiring body 4 is placed on upper end surfaces thereof. This allows the flexible wiring body 4 to be held over the predetermined gap with respect to the substrate 2 via the base portions 56. Further, the electronic component 3 itself can be held over the predetermined gap with respect to the flexible wiring body 4 via the pins 57 projecting upward from the base portions 56.

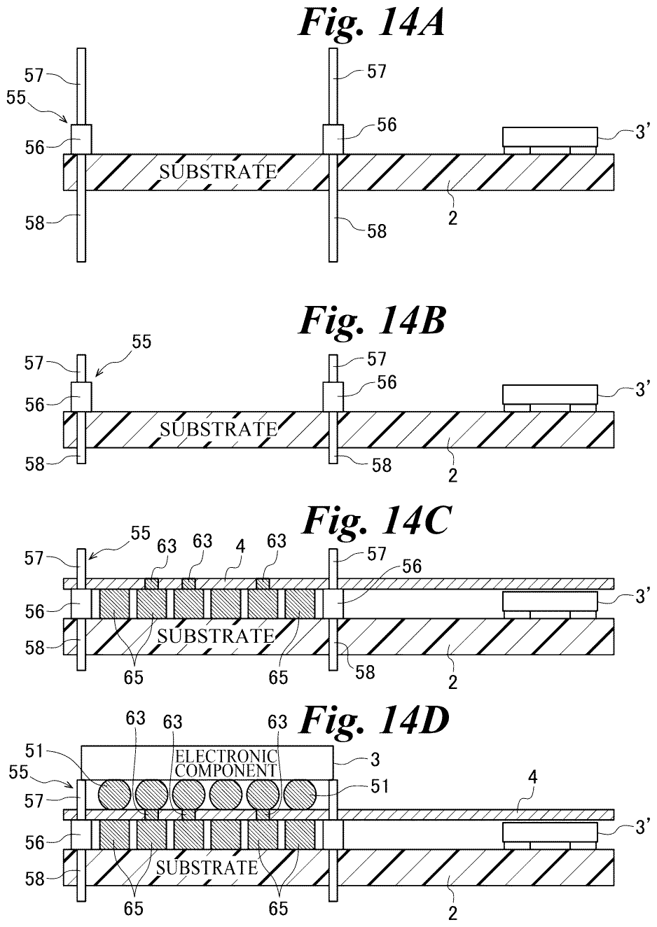

When such a gap holding body 55 is provided, as illustrated in FIG. 14A, first, the pins 58 of the gap holding bodies 55 are inserted into the substrate 2. Subsequently, as illustrated in FIG. 14B, the inserted pins 58 and the pins 57 projecting upward from the base portion 56 are cut by a desired length. Subsequently, as illustrated in FIG. 14C, the flexible wiring body 4 is placed on the base portions 56. Before the flexible wiring body 4 is placed, the conductive portions 65 may be formed on the substrate 2. Subsequently, as illustrated in FIG. 14D, the electronic component 3 is placed on the pins 57. Before the electronic component 3 is placed, the conductive portions 51 may be formed between the flexible wiring body 4 and the electronic component 3.

In the case of the example of FIG. 14, the base portion 56 is designed such that a distance between the substrate 2 and the flexible wiring body 4 becomes 0.4 mm, and the pin 57 is designed such that a distance between the flexible wiring body 4 and the electronic component 3 becomes 0.4 to 0.6 mm, but the sizes are not limited thereto. However, the implementation method is not limited thereto.

The gap between the substrate 2 and the flexible wiring body 4 and the gap between the flexible wiring body 4 and the electronic component 3 are held with the gap holding body 55 by a predetermined amount, thereby allowing the flexible wiring body 4 to avoid contact with the substrate 2 and the electronic component 3 and allowing improvement of the heat dissipation performance.

Since the present invention with the above-described configuration can achieve the wiring via the flexible wiring body 4, a general-purpose product is applicable to the substrate 2.

In a multi-layer wiring board, because of an increase of wiring density, X-Y wiring in which wiring layers are switched with vias is often used, but the present invention in which the electronic components 3 are mutually connected via the flexible wiring body 4 can achieve wiring without vias using the flexible wiring body 4, and the wiring density can be improved without an influence on the transmission loss.

Since the flexible wiring body 4 can be provided out of contact with the substrate 2, the shortest wiring between the electronic components 3 can be performed at any angle. Providing the predetermined amount of the gap between the substrate 2 and the flexible wiring body 4 allows the other electronic component 3′ to be provided between the substrate 2 and the flexible wiring body 4 as illustrated in FIG. 8, thus allowing improvement of component arrangement density, and eventually allowing the degree of freedom of circuit design of the substrate to be enhanced.

According to the present invention, since the electronic components 3 are directly electrically connected to one another via the flexible wiring body 4, when a signal is extracted from the electronic component 3, it is not necessary to provide a connector at the electronic component 3 or in the proximity of the electronic component 3, and it is also not necessary to provide lead-out wiring of a connector from the electronic component 3. Therefore, the present invention can reduce an area for installing a connector. An increase of the transmission loss due to the installation of a connector can be reduced. In view of this, the present invention reduces the restriction for circuit design, and increases the degree of freedom.

Further, since the present invention has the structure in which the flexible wiring body 4 is interposed between the electronic component 3 and the substrate 2, not the structure in which the electronic component 3 is directly connected to the substrate 2, when a part of the electronic components 3 breaks down, the convenience in the repair thereof can be improved.

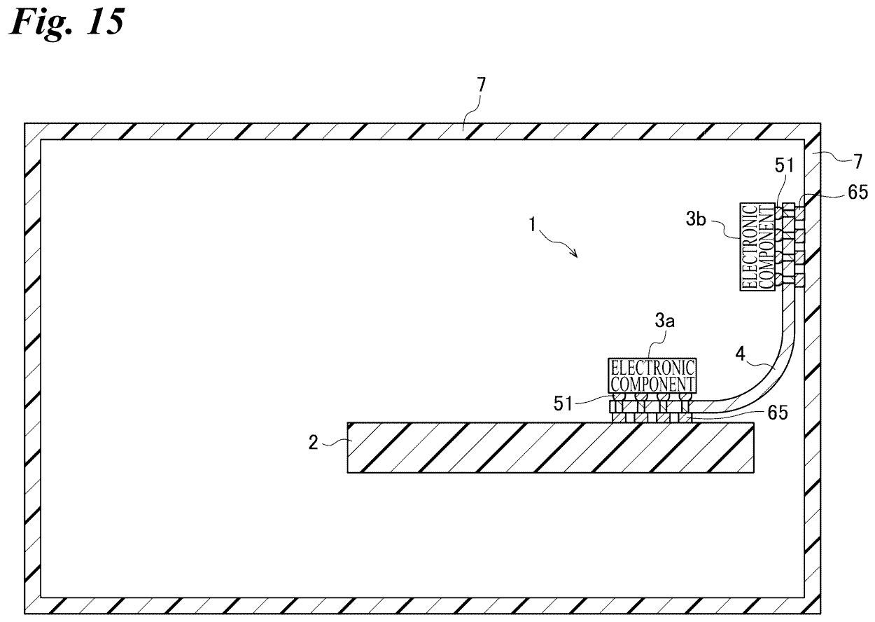

According to the present invention, as illustrated in FIG. 15, the wiring structure 1 may be provided in a housing 7 instead of the substrate 2. In this case, the wiring structure 1 provided at the housing 7 side includes the housing 7, two or more electronic components 3b installed on the housing 7, and the flexible wiring body 4 interposed between the housing 7 and the electronic component 3. For the detailed configuration of the embodiment illustrated in FIG. 15, by replacing the substrate 2 in the above-described description with the housing 7, the description is omitted below.

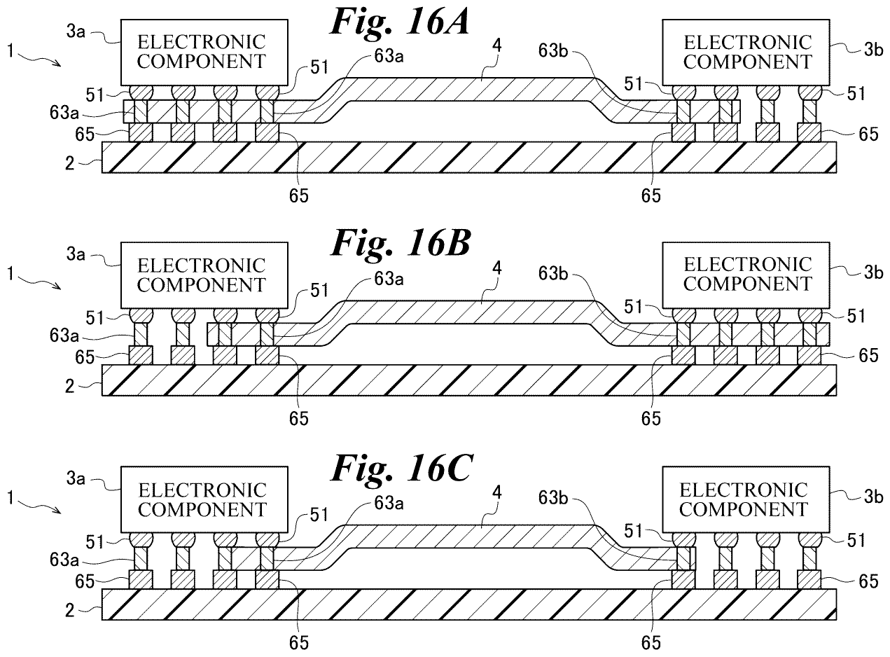

In the present invention, as illustrated in FIGS. 16A to 16C, it is not necessary that all of the conductive portions 51, the conductive portions 63, and the conductive portions 65 are electrically connected to the flexible wiring body 4 with respect to the electronic component 3, and a part of the conductive portions 51, the conductive portions 63, and the conductive portions 65 may be directly electrically connected to the substrate 2 similarly to the conventional one. In this case, the flexible wiring body 4 does not need to be extended to the area of the conductive portion 51, the conductive portion 63, and the conductive portion 65 directly electrically connected to the substrate 2.

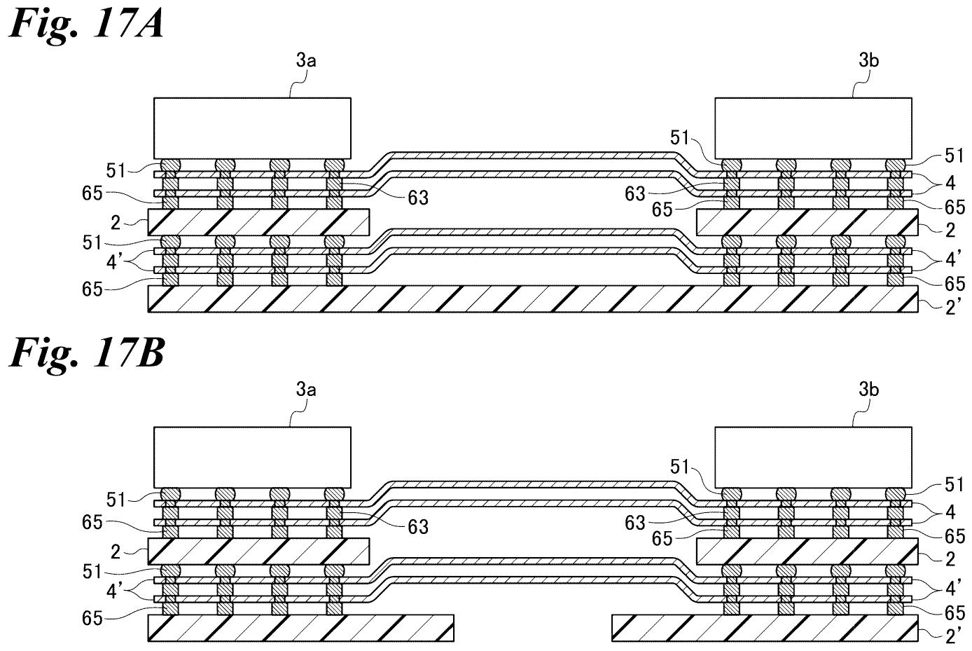

FIG. 17 illustrates an example in which another substrate 2′ provided below the substrate 2 is further included. Other flexible wiring bodies 4′ are further interposed between the substrate 2 and the other substrate 2′. The flexible wiring body 4′ has a wiring portion 411 electrically connected to the substrate 2 via the conductive portions 65. At this time, it is needless to say that the wiring portion 411 of the flexible wiring body 4′ may be electrically connected to not only the substrate 2 but also the other substrate 2′ further via the conductive portions 65. FIG. 17A illustrates an example of the formation on one other substrate 2′, and FIG. 17B illustrates an example of the formation on the substrates 2′ configured as separate bodies to one another.

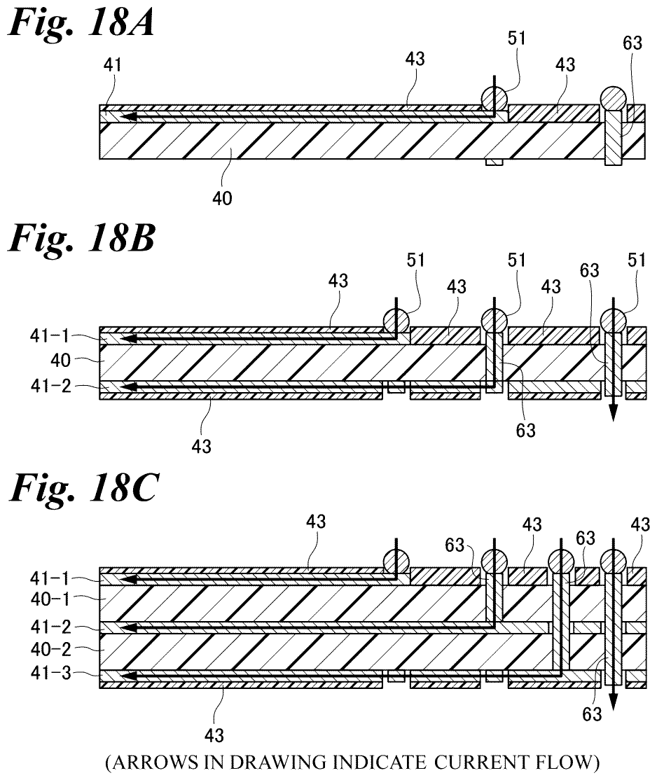

FIG. 18A illustrates an example in which the flexible wiring body 4 is configured of what is called a single-sided board including a single layer of the conductor portion 41. Only the conductor portion 41 achieves the electrical connection via the conductive portion 51.

FIG. 18B illustrates an example in which the flexible wiring body 4 is configured of what is called a double-sided board including two layers of the conductor portions 41-1, 41-2. The conductor portions 41-1, 41-2 are configured in two layers so as to sandwich the base material 40. Only the conductor portion 41-1 may be directly electrically connected via the conductive portion 51, or only the conductor portion 41-2 may be directly electrically connected via the conductive portion 51a with a configuration in which the conductive portion 63 is connected to only the conductor portion 41-2 and separated from the conductor portion 41-1. Further, the conductive portion 63 may be separated from the conductor portions 41-1, 41-2 to be electrically connected to only the substrate 2.

FIG. 18C illustrates an example in which the flexible wiring body 4 is configured of what is called a multi-layer board including three layers of the conductor portions 41-1, 41-2, 41-3. A base material 40-1 is interposed between the conductor portion 41-1 and the conductor portion 41-2. Abase material 40-2 is interposed between the conductor portion 41-2 and the conductor portion 41-3.

In this case, similarly, a current to be made to flow to each of the conductor portions 41-1, 41-2, 41-3 can be connected in parallel/series depending on whether the conductive portion 63 is one that reaches the conductor portion 41-1 or one that reaches the conductor portion 41-2 or 41-3, and it is needless to say that the conductor portions 41-1, 41-2, 41-3 to which a current is not to be made to flow may be spaced as necessary. The conductor portion 41 (the wiring portion 411) may be configured of a single-sided board with one layer of the wiring portion, a double-sided board with two layers of the wiring portion, or a multi-layer board with three or more layers of the wiring portion. However, the double-sided board with two layers of the wiring portion and the multi-layer board with three or more layers of the wiring portion more easily reduce the transmission loss and more easily improve the heat dissipation performance than the single-sided board with one layer of the wiring portion.

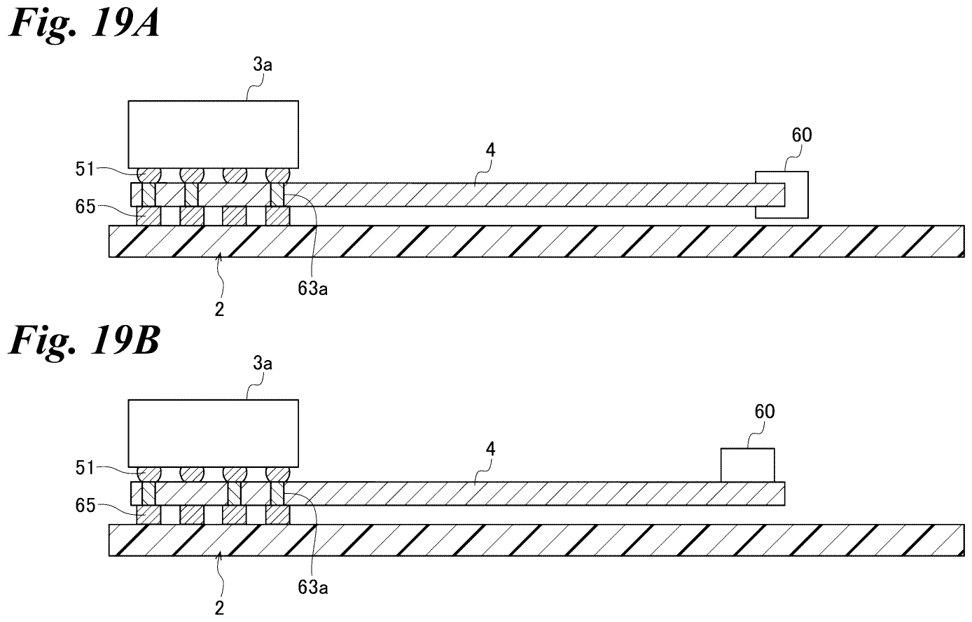

FIG. 19 illustrates an example in which the flexible wiring body 4 has one end side provided with the above-described wiring portion 411 (the connection points 412, 413, 414) and the other end side connected to a connector 60. It is needless to say that such a configuration provides the above-described effects. However, the configuration is not limited thereto, and since the configuration illustrated in FIG. 19 is also included in the present invention, it is only necessary to provide the connection points 412, 413, 414 at the flexible wiring body 4.

### DESCRIPTION OF REFERENCE SIGNS

1: Wiring structure
2: Substrate (printed wiring board)
3: Electronic component
4: Flexible wiring body
7: Housing
21: Conductor portion of substrate 2
31: Terminal
40: Base material
41: Conductor portion of flexible wiring body 4
43: Coating layer
51: Conductive portion
55: Gap holding body
56: Base portion
57, 58: Pin
60: Connector
61: Hole
63, 65: Conductive portion
411: Wiring portion
412, 413, 414: Connection point

1. A wiring structure of electronic components, comprising:
a substrate; and
a flexible wiring body interposed between the substrate and an electronic component installed on the substrate, the flexible wiring body being provided with a conductive wiring portion and having flexibility, wherein
the wiring portion of the flexible wiring body is electrically connected to the electronic component and/or the substrate,
the flexible wiring body, the substrate, and the electronic component are directly electrically connected in an area in which the flexible wiring body is interposed, and
the wiring portion of the flexible wiring body electrically connects two or more mutually spaced electronic components installed on the one substrate to one another, and an area of the flexible wiring body between the electronic components is separated from the substrate.

2. The wiring structure of electronic components according to claim 1, wherein
the wiring portion provided at any one end side or both end sides of the flexible wiring body electrically connects the two or more electronic components installed on the one substrate to one another, or electrically connects the electronic components set on the respective two or more substrates to one another.

3. The wiring structure of electronic components according to claim 1, wherein
a plurality of the flexible wiring bodies are stacked, and
the wiring portions of the respective flexible wiring bodies are electrically connected to the one electronic component.

4. The wiring structure of electronic components according to claim 1, further comprising
another substrate provided below the substrate, wherein
another flexible wiring body is further interposed between the substrate and the other substrate, and the other flexible wiring body includes a wiring portion electrically connected to the substrate.

5. The wiring structure of electronic components according to claim 1, wherein
the wiring portion of the flexible wiring body is provided at each layer of two or more layers of conductor portions.

6. A wiring structure of electronic components, comprising:
a housing; and
a flexible wiring body interposed between the housing and an electronic component installed on an inner wall surface that functions as a substrate of the housing, the flexible wiring body being provided with a conductive wiring portion and having flexibility, wherein
the wiring portion of the flexible wiring body is electrically connected to the electronic component and/or a wiring portion formed on the inner wall surface of the housing,
the flexible wiring body, the inner wall surface of the housing, and the electronic component are directly electrically connected in an area in which the flexible wiring body is interposed, and
the wiring portion of the flexible wiring body electrically connects two or more mutually spaced electronic components separately installed on the inner wall surface and another substrate to one another, and the electronic components at the flexible wiring body are spaced.

7. A connection method of electronic components, comprising:
interposing a flexible wiring body that is provided with a conductive wiring portion and has flexibility between a substrate and an electronic component installed on the substrate such that the wiring portion is electrically connected to the electronic component and/or the substrate;
directly electrically connecting the flexible wiring body, the substrate, and the electronic component in an area in which the flexible wiring body is interposed; and
electrically connecting two or more mutually spaced electronic components installed on the one substrate to one another by the wiring portion of the flexible wiring body, and separating an area of the flexible wiring body between the electronic components from the substrate.

8. The connection method of electronic components according to claim 7, wherein
the wiring portion provided at any one end side or both end sides of the flexible wiring body electrically connects the two or more electronic components installed on the one substrate to one another, or electrically connects the electronic components set on the respective two or more substrates to one another.

9. The connection method of electronic components according to claim 7, wherein
when a plurality of the flexible wiring bodies are stacked, the wiring portions of the respective flexible wiring bodies are electrically connected to the one electronic component.

10. The wiring structure of electronic components according to claim 2, wherein
a plurality of the flexible wiring bodies are stacked, and
the wiring portions of the respective flexible wiring bodies are electrically connected to the one electronic component.

11. The wiring structure of electronic components according to claim 2, further comprising
another substrate provided below the substrate, wherein
another flexible wiring body is further interposed between the substrate and the other substrate, and the other flexible wiring body includes a wiring portion electrically connected to the substrate.

12. The wiring structure of electronic components according to claim 2, wherein
the wiring portion of the flexible wiring body is provided at each layer of two or more layers of conductor portions.

13. The connection method of electronic components according to claim 8, wherein
when a plurality of the flexible wiring bodies are stacked, the wiring portions of the respective flexible wiring bodies are electrically connected to the one electronic component.
